(19) United States
(12) Patent Application Publication
(10) Pub. No.: US 2008/0169539 A1
(43) Pub. Date: Jul. 17, 2008

(54) Under bump metallurgy structure of a package and method of making same

(75) Inventors: Sychyi Fang, Palo Alto, CA (US); Wen Kun Yang, Hsin-Chu (TW); Chen Lung Tsai, Saratoga, CA (US)

Correspondence Address: DLA PIPER US LLP, 2000 UNIVERSITY AVENUE, E. PALO ALTO, CA, 94303-2248, US

(73) Assignees: Silicon Storage Tech., Inc.; Adv. Chip Eng. Tech., Inc.

(21) Appl. No.: 11/653,725

(22) Filed: Jan. 12, 2007

(51) Int. Cl. H01L 23/495; H01L 21/00

(52) U.S. Cl. 257/676; 438/123; 257/E23.031; 257/E21.001

(57) ABSTRACT

A package for a semiconductor integrated circuit die comprises a redistributed layer formed over a first barrier layer electrically connected to a bonding pad of a die. A second barrier layer is formed over the redistributed layer. A multi-metal layer is formed over the second barrier layer for coupling to a solder ball, wherein the multi-metal layer has an extending part that extends outside a second opening over the upper of the second dielectric layer to prevent tin infiltration from the solder ball to the redistribution layer.

### TECHNICAL FIELD

The present invention relates to an under bump metallurgy (UBM) structure in a semiconductor package, and more particularly, to a UBM scheme to prevent tin infiltration.

### BACKGROUND OF THE INVENTION

As integrated circuits (IC) advance toward higher speeds and larger pin counts, conventional technologies for achieving fine-pitch wire bonding structures cannot keep pace with the demand resulting from increased IC chip processing speeds and higher IC chip pin counts due to traditional wire bonding technologies that have approached or even reached their limits. As such, the current trend is to replace wire bonding structures with other package structures and assembly, such as a flip chip packages and a wafer level packages (WLP).

Some chip bonding technologies utilize a copper bump attached to a contact pad on the chip to make an electrical connection for signal input and output. For instance, new packaging methods include BGA (Ball Grid Array) and CSP (Chip Scale Package) methods where semiconductor chips are mounted on a substrate, such as a printed circuit board. In flip chip bonding, bumps are usually formed beforehand on the bonding pads of a semiconductor chip and the bumps are then interfaced with the terminals located on an interconnect substrate followed by, for example, thermo-compression bonding. A mounting technology known as “chip on glass” has emerged as a cost effective technique for mounting driver chips using a flat-top metal bump, for example a copper bump. See for example U.S. patent application 2005/0124093 published on Jun. 9, 2005, and U.S. patent application 2005/0236696 published on Oct. 27, 2005. Copper bumps may be formed by electro-deposition methods of copper over layers of Under Bump Metallurgy (UBM) formed over the chip bonding pad. The copper bump (column) is typically formed within a mask formed of photo resist or other organic resinous material defining the bump forming area over the chip bonding pad.

In addition, the use of solder bumps in attaching die to flip-chip packaging is well known in the art. In such a structure, a die is provided which has an I/O pad or die pad disposed thereon. A photo polymer passivation layer is provided to protect the die from damage during processing. A UBM structure is disposed on the die pad, and a solder ball is placed or formed on top of the UBM structure. As is well known in the art, the solder ball is used to form an electrical and mechanical connection between the die and a Printed Circuit Board (PCB) or other device. A significant factor affecting solder joint life is the UBM structure employed in conjunction with the solder joint. However, existing UBM schemes have been designed to optimize metallurgical or processing parameters rather than to improve the reliability of solder joints. In the conventional package scheme, tin infiltration will occur. Tin from the solder will infiltrate through the structure of the UBM to the bonding pads. For example, if the UBM interface comprises copper and the solder ball is a tin-lead alloy, tin filtration will likely occur. If tin filtration occurs, this causes the copper metal to become brittle and more rigid, decreasing reliability during temperature cycling test, at the package level and board level.

Referring to FIG. 1 there is shown a cross-sectional view of a bonding structure of the prior art. In this embodiment, a silicon substrate die 101 with integrated circuits formed thereon has an aluminum bonding pad 102. A passivation layer 103 of silicon nitride is formed on the silicon substrate 101. A first dielectric layer 104 of BCB or photoinitiator (PI) is formed on the passivation layer 103. A first opening is created in the first insulating layer 104 and passivation layer 103. A barrier metal layer 105, such as Ti/Cu is sputtered on the first insulating layer 104 including in the first opening. A layer of copper 106 is electroplated on the barrier metal layer 105. A layer 107 of nickel is then electro plated onto the layer 106 of copper. Gold 107 is then electroplated onto the layer 107 of nickel. Finally, a solder ball 109 is formed on the layer 108 of gold. Because the solder ball 109 typically contains tin, tin infiltration into the metal layers 107/106/105 can occur. During temperature cycling, the tin infiltration can cause the metal layers 107/106/105 to break.

Referring to FIG. 2, there is shown a cross-sectional view of another bonding structure of the prior art. In this embodiment, which is disclosed in U.S. Pat. No. 7,005,752, similar to the prior art structure shown in FIG. 1, the structure shown in FIG. 2 comprises a silicon substrate die 201 with integrated circuits formed thereon has an aluminum bonding pad 202. A passivation layer 203 of silicon nitride is formed on the silicon substrate 201. A first dielectric layer 210 of BCB or photoinitiator (PI) is formed on the passivation layer 203. A first opening is created in the first insulating layer 210 and passivation layer 203. A barrier metal layer 205, such as Ti/Cu is sputtered on the first insulating layer 210 including in the first opening. A metal layer 206, such as TiW/Cu is also sputtered on the barrier metal layer 205. A solder ball 207 is deposited on the sputtered metal layer 206. The disadvantage of the structure shown in FIG. 2 is that the sputtered layers 206/205 are typically quite thin, and can cause inter-metal connection problems. Moreover, solder ball stress impacts Al pad without any buffer. Thus, during temperature cycling, the metal can break.

In view of the aforementioned drawbacks, what is required is a new UBM structure for package and the method to solve the above drawbacks.

### SUMMARY OF THE INVENTION

A metallization structure for a semiconductor integrated circuit package has a semiconductor integrated circuit die, with a bonding pad formed thereon. A first dielectric layer having a first opening is formed over the die. A first metal layer is formed within the first opening and over the bonding pad, and extends over the first dielectric layer. A redistributed metal layer is formed within the first opening and over the first metal layer. A multi-metal layer is formed over the redistributed metal layer, wherein the multi-metal layer includes a first barrier metal layer, and a second metal layer formed on the first barrier metal layer. The multi-metal layer has a dimension to support a solder ball, to prevent metal in the solder ball from migrating into the redistributed metal layer.

The present invention also relates to a method of creating an under bump metallization for the foregoing described semiconductor package.

### BRIEF DESCRIPTION OF THE DRAWINGS

The above objects, and other features and advantages of the present invention will become more apparent after reading the following detailed description when taken in conjunction with the drawings, in which:

FIG. 1 is a schematic diagram of one embodiment of a metallurgy structure of the prior art.

FIG. 2 is a schematic diagram of another embodiment of a metallurgy structure of the prior art.

FIG. 3 is a schematic diagram of an under bump metallurgy structure on aluminum pads of a die according to the present invention.

FIG. 4 is a schematic diagram of an under bump metallurgy structure on RDL metal layer of a package according to the present invention.

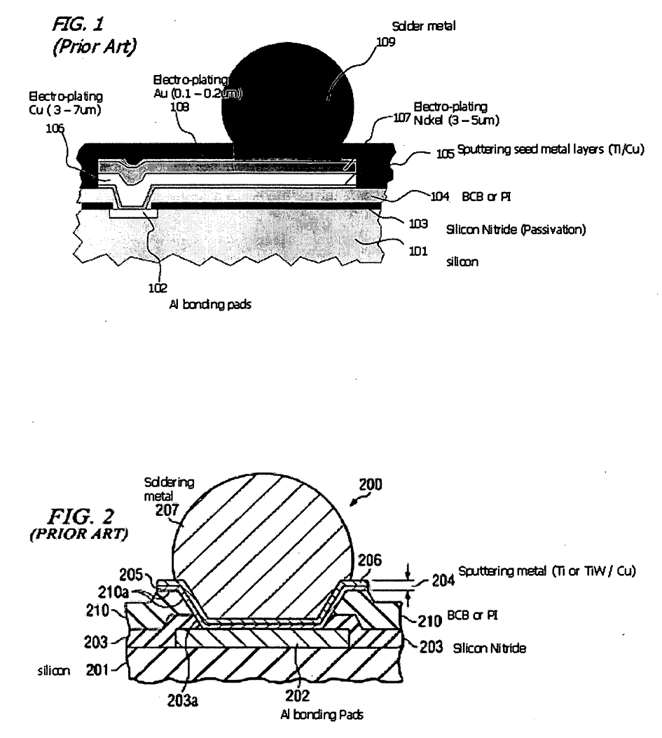

### DETAILED DESCRIPTION OF THE INVENTION

The present invention discloses an under bump metallurgy structure for semiconductor package of a die and method of the same. It can also be applied to a wafer level package. Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims.

A new Under Bump Metallurgy (UBM) layer is disclosed herein which is especially suitable for use with a Wafer Level Chip Scale Package (WLCSP). The UBM dramatically improves package lifetime, and also avoids tin infiltration issue. The mechanical properties of the solder joint is further improved by providing a larger area of contact between the material of the UBM and the solder material, thereby improving the integrity of the solder-UBM interface. In the case of prior art, the inter-diffusion of these materials diminishes the likelihood of solder fatigue along the interface.

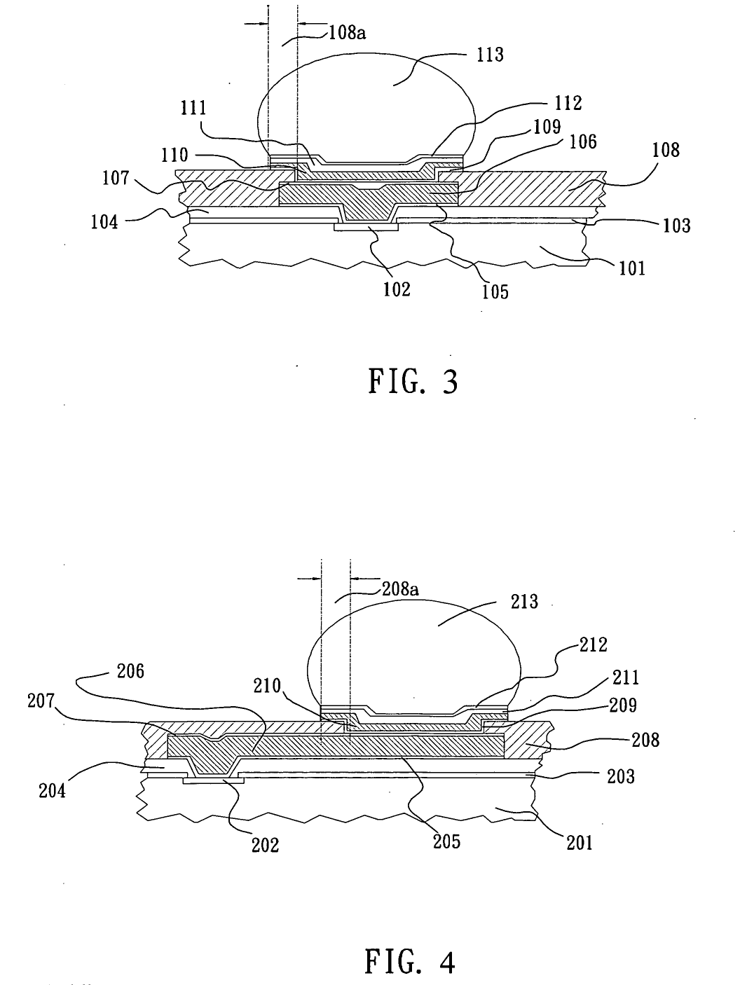

Of course, this procedure may be modified slightly through appropriate definition of the photo resist if a UBM structure is desired. Examples of the UBM structure of the present invention are illustrated in FIGS. 3 and 4, and they are understood that many variations of this embodiment exist. These structures are useful for forming solder bumps on a device designed for wire bonding, a situation that often requires redistribution of the bonding pads.

Referring to FIG. 3, there is shown a cross sectional view (greatly exaggerated) of a UBM structure on Al bonding pads of a die according to the present invention. A silicon substrate or die 101 is provided. A passivation layer 103, such as BPSG, is formed on the silicon substrate 101. An elastic dielectric layer 104, which may be, for example, a material such as BCB, SINR (Siloxanes polymer), epoxy, polyimides or resin is then deposited, and partially over, the passivation layer 103. The elastic dielectric layer 104 may be formed by printing, coating, or employing a photolithography process and an etching process to remove partial elastic dielectric layer to create a first opening to expose the bonding pads 102, typically made of aluminum. Next, a first barrier metal layer 105 is formed within the first opening and over the bonding pads 102. In order to provide for proper placement and pitch of the solder bumps that are to be introduced at a later stage, a redistributed layer (RDL) may be formed on the first barrier metal layer 105. In the present invention, the redistributed layer may comprise a first layer of copper or copper alloy 106 and a second layer of gold or gold alloy 107. For example, the layer 106 typically has a layer thickness within the range of about 5 micron to about 20 micron, preferably within the range about 8 micron to about 15 micron, and the layer 107 typically has a layer thickness within the range of about 0.05 micron to about 0.5 micron, preferably within the range about 0.1 micron to about 0.25 micron. Because the RDL layer 106/107 is wider than the opening in the dielectric layer 104, the RDL layer 106/107 re-distributes the force that is applied on the solder ball 113, so that it does not impact only on the bonding pad 102. This redistribution of force releases stress during the temperature cycling test.

Next, an elastic dielectric layer 108 is deposited, and partially over, the RDL 106/107 to protect the RDL 106/107. The elastic dielectric layer 108 may be formed by printing, coating, or employing a photolithography process and an etching process to remove partially the elastic dielectric layer 108 to create a second opening to expose the RDL 106/107. In this approach, the shape of the UBM is defined primarily by the patterned elastic dielectric layer 108. A photo definable epoxy can be optionally coated onto a wafer to serve as a Stress Compensation Layer (SCL).

Alternatively, the elastic dielectric layer 108 may be employed as the SCL. For example, the elastic dielectric layer 108 typically has a layer thickness within the range of about 10 micron to about 50 micron, preferably within the range about 20 micron to about 35 micron. In a typical embodiment, the elastic dielectric layer 108 comprises a material such as BCB, SINR (Siloxane polymer), epoxy, polyimides, resin, diluent, filler or photoinitiator. The epoxy is preferably an aromatic epoxy such as bisphenol A diepoxide or bisphenol F diepoxide. Useful fillers include, for example, borosilicate glass, quartz, silica, and spherical glass beads. Useful diluents include, for example, aliphatic epoxies or cycloaliphatic epoxies which have a lower index of refraction than the aromatic epoxy being used. Thus, for example, if bisphenol F diepoxide is used as the aromatic epoxy, the diluent may be an aliphatic epoxy such as diglycidyl-1,2-cyclohexanedicarboxylate, limonene oxide, 3,4-epoxycyclohexylmethyl 3,4-epoxycyclohexane carboxylate, or partially acrylated bisphenol F diepoxide. Moreover, various other polymers can also be utilized in the practice of the present invention.

In addition, various materials can be used for the SCL described above. The material or materials used in this role will have physical properties which serve to protect the semiconductor IC die and package from stress and strain arising from any differences in coefficients of thermal expansion between the semiconductor die 100 and a support (e.g., a PCB) to which the die 101 may be attached. The SCL may also serve as a mask or stencil for solder ball placement.

Moreover, it may also be desirable in some situations to have the SCL layer also serve as a passivation layer. Preferably, the material used for the SCL layers in devices made in accordance with the present invention will be a Si3N4, SiON, and/or SiO2 may also be used. Various materials may be used as passivation layers in the devices and methodologies described herein. Passivation layers serve to protect the wafer from damage during processing. The passivation layer also serves to isolate the active sites on the wafer. It is preferred that the passivation material is a photo definable material such as BenzoCycloButene (BCB), since this allows the use of photolithographical techniques to expose the die pad. Other suitable materials for use in the passivation layer include, but are not limited to, polyimides, silicon nitride, and silicon oxide. In order to function as an effective SCL, it is typically necessary for the SCL to have a Coefficient of Thermal Expansion (CTE) that closely matches that of the adjacent die.

Subsequently, a multilayered UBM structure is formed. In a typical embodiment, the multilayered UBM structure of the present invention comprises a barrier seed metal layer 109 and a multi-metal layer. The barrier seed metal layer 109 may be sputtered onto the elastic dielectric layer 108 and on the sub-layer 107 of RDL or pad (in the event there is no RDL). In one embodiment, the barrier seed metal layer 109 is placed a photolithography process and an etching process to form a predetermined pattern. The layer 109 is preferably Ti-containing and Cu-containing layer. For example, the Ti-containing layer 109 may be based on a variety of materials or alloys, including, without limitation, Ti, Ta, Ti—W, Ti—N or Ta—N alloys. In addition, the barrier seed metal layer 109 typically has a layer thickness within the range of about 0.5 micron to about 1 micron, preferably within the range about 0.6 micron to about 0.8 micron. In other words, a variety of materials and combinations of materials may be used in the practice of the methodologies described herein to facilitate adhesion of the UBM to the layer 107. The material or materials used for this purpose may also serve other functions, such as providing a barrier seed metal layer 109 for electroplating operations used to form the UBM.

In one embodiment, a photo-resist patterning step is executed before performing the electroplating Cu/Ni/Au layer 110-112. In other words, a photo-resist pattern is formed on the elastic dielectric layer 108 or the barrier seed layer 109. If desired, however, and if the layer of photo resist is sufficiently thick, it may be removed after solder placement and reflow, again by chemical stripping or by other suitable means. In one embodiment, the photo-resist pattern covers partially the barrier seed metal layer 109 such that the predetermined UBM pattern constitutes a U-shape. After photo-resist defining UBM pattern, the electro-plating Cu/Ni/Au layer 110-112 selectively deposits on exposed Ti//Cu barrier seed metal layer 109 area only. The barrier seed metal layer 109 and/or the multi-layer 110-112 have an extending part 108a that extends outside the opening in the dielectric layer 108 and is on the upper surface of the dielectric layer 108. The length of the extending part 108a on the dielectric layer 108 is about 10 micron to 50 micron. The extending part 108a is used to prevent tin from the solder ball 113 infiltrating into the RDL layer 106/107. In particular, the length of the extending portion 108 is such that it can support the solder ball 113, such that the tin from the solder ball 113 does not infiltrate or migrate through the barrier seed metal layer 109 and the multi-layer 110-112 and into the RDL layer 106/107. The composition of the barrier seed metal layer 109 is such that it does not permit tin to pass therethrough. This can be accomplished by the dimension of the barrier seed layer 109 and the multi-layer 110-112 being longer than the RDL layer 106/107, as shown in FIG. 3. In that case, in the event the tin from the solder ball 113 infiltrates or migrates outside past the barrier seed layer 109 and the multi-layer 110-112, and into the second dielectric layer 108, it will not enter or migrate into the RDL layer 106/107. In short length of the barrier seed layer 109 and the multi-layer 110-112 acts as a shield for the tin from the solder ball 108a. Alternatively, as shown in FIG. 3, the length of the extension 108a is such that it is of a size to contain the tin from the solder ball 113 to enter into the second dielectric layer 108. In this manner, although the “left” hand portion of the extension 108a is not sufficiently long to shield the entire RDL layer 106/107, the extension 108a is long enough to “contain” the tin from the solder ball 113 from entering into the second dielectric layer 108. Thus, as used in the claims, the phrase “to prevent metal in said solder ball from migrating into the said redistributed metal layer” encompasses both of these concepts. The length 108a could be defined by the opening dimension of the photo-resist.

As the same mentioned above, various materials may be used in the construction of the metal layer of UBM structures of the type disclosed herein. In a typical embodiment, the multilayered metal layer structure of the present invention comprises three metal layers 110, 111 and 112. The first metal layer 110 may be made out of copper. Thus, the first metal layer 110 may be formed by employing an electroplating process with a copper solution. For example, the first metal layer 110 typically has a layer thickness within the range of about 2 micron to about 5 micron, preferably within the range about 2.5 micron to about 3.5 micron. Pure copper is especially preferred, because it can be readily electroplated using well established methods to almost any desired thickness. Copper structures with inherently low internal stress can be formed by electroplating processes. By contrast, other metal, such as nickel, can form the second metal layer 111 to the thicknesses contemplated by the present invention without the occurrence of deformation or structural failure brought about by internal stresses.

Similarly, the second metal layer 111 may be formed by employing an electroplating process with a nickel solution. In addition, the second metal layer 111 typically has a layer thickness within the range of about 2 micron to about 5 micron, preferably within the range about 2.5 micron to about 3.5 micron. Copper also readily inter-diffuses with commonly used Sn—Pb solders during reflow to form an inter-metallic zone that reduces fracturing along the solder-UBM interface. Moreover, copper has relatively high tensile strain which ensures that any stress fractures which occur will occur in the solder portion of the solder joint, rather than in the die or UBM structure. Next, another metal, such as gold, forms the third top metal layer 112. Similarly, the top metal layer 112 may be formed by employing an electroplating process with a gold solution. In a typical embodiment, the top metal layer 112 typically has a layer thickness within the range of about 0.1 micron to about 0.5 micron, preferably within the range about 0.15 micron to about 0.35 micron.

In addition to copper, nickel and gold, a number of other materials may be used in the construction of UBM structures of the type disclosed herein. These materials include Ag, Cr, Sn, and various alloys of these materials, including alloys of these materials with copper. In some embodiments of the UBM structures described herein, the UBM may have a multilayered structure. Thus, for example, in some embodiments, such multilayered UBMs include, but not limited to, Ti/Cu—Cu—Ni, structures or Ti/Cu—Cu—Ni—Au structures.

Next, the photo-resist pattern is then stripped, through the application of a solvent or by other suitable means, and the barrier seed layer 109 and the metal layers 110, 111 and 112 form the UBM structure. Therefore, the UBM structure (109-112) is formed over the bonding pad 102. As indicated above-mentioned, the UBM structure is substantially a U-shape, especially the extending part 108a (UBM overlay area) of the UBM structure and the length of the extending part 108a over the dielectric layer 108 is about 10 micron to 50 micron to avoid the tin infiltration.

The UBM structures employed in the methods and devices described herein may take on a variety of shapes consistent with the considerations described herein. Preferably, the UBM will have an interior surface that is rounded and bowl-shaped, or is columnar or stud-shaped, and which forms a suitable receptacle for a solder composition. However, the use of a SCL as described herein provides for the formation of a wide variety of UBM shapes and dimensions.

A soldering metal ball 113 is placed onto the UBM structure. A suitable flux may be used to prepare the surface of the UBM for solder application. The solder composition 113 may then be applied by a ball drop, screen printing, or by other suitable methodologies. The solder composition is then reflowed to yield the solder bumps 113. The resulting structure may then be cleaned and cured as necessary.

The processes described above are very clean and compatible with wafer processing. The placing of the solder bump 113 on the UBM structure (109-112) can be accomplished through standard, well-known processes and hence has a good yield. Since there is no molten solder extrusion into any voids or cracks as may exist in the layers, no solder migration or electrical failures occur. There are also no adhesion issues between the RDL and the UBM structure. These processes provide low cost, high reliability wafer level packages. These processes also provide a way to deliver a known good package using manufacturing processes compatible with wafer processing and done on the full wafer.

A variety of solders may be used in conjunction with the structures or methodologies disclosed herein. Useful solders include both eutectic and non-eutectic solders, and may be in the form of solids, liquids, pastes or powders at room temperature. Such solders may be based on a variety of materials or alloys, including Sn—Pb, Sn—Pb—Ag, Sn—Ag—Cu, Sn—Ag, Sn—Cu—Ni, Sn—Sb, Sn—Pb—Ag—Sb, Sn—Pb—Sb, Sn—Bi—Ag—Cu, and Sn—Cu.

As the results of the previous figures indicate, it is not always possible to optimize one design characteristic without adversely affecting another design characteristic. Thus, for example, a design might have very high solder joint reliability but, because of the high stresses in the UBM structure, it might be prone to material failure. A good design is shown in FIG. 3. As indicated by this analysis, the packages proposed herein are predicted to have a higher life time. They also overcome the drawbacks of the conventional bump design.

Thus far, the details of some specific embodiments of the structures and methodologies disclosed herein have been described. However, a number of variations in different features of these methodologies and structures are possible. Some of these possibilities are described below. As described herein, various methods have been provided which make advantageous use of a photo-definable polymer to create UBMs of various shapes and dimensions. Various structures that can be made through the use of these methods have also been provided. The methods disclosed herein can be used to create UBMs that are found to improve some of the mechanical characteristics of the solder joint. The methods disclosed herein can also be used to create UBMs which facilitates placement of a solder ball on the UBM. These various features, taken alone or in combination, are found to have profound, beneficial effects on package reliability and lifetime.

With reference to FIG. 4, there is shown another cross-sectional view of an UBM structure on RDL trace of a package according to the present invention. It is noted that it is another location view of the UBM structure on the RDL trace. The numbers 201˜213 indicated in FIG. 4 correspond one-to-one directly with the numerals 101˜113 shown and described in FIG. 3.

The present invention has the advantages as follows: high reliability, avoiding tin infiltration, improving SMT solder join, especially LGA, and improving T/C stress releasing. In addition, the present invention can apply to a conventional package and wafer level package etc.

The above description of the invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A metallization structure for a semiconductor integrated circuit package, comprising:
a semiconductor integrated circuit die having a bonding pad formed thereon;
a first dielectric layer having a first opening formed therein over said die;
a first metal layer formed within said first opening and over said bonding pad, and extending over said first dielectric layer;
a redistributed metal layer formed within said first opening and over said first metal layer; and
a multi-metal layer formed over said redistributed metal layer, wherein said multi-metal layer include a first barrier metal layer, and a second metal layer formed on said first barrier metal layer; said multi-metal layer having a dimension to support a solder ball, to prevent metal in said solder ball from migrating into said redistributed metal layer.

2. The structure of claim 1, further comprising a second dielectric layer over said first dielectric layer and said redistributed metal layer; said second dielectric layer having a second opening exposing said redistributed metal layer, wherein said multi-metal layer is deposited in said second opening and is in contact with said redistributed metal layer, and wherein said multi-metal layer further extends over said second dielectric layer.

3. The structure of claim 1, wherein said first metal layer comprises titanium, copper and the combination thereof.

4. The structure of claim 1, wherein said redistributed metal layer comprises a first metal layer including copper and a second metal layer including gold.

5. The structure of claim 2, wherein said first barrier metal layer is formed within said second opening and over said redistributed metal layer.

6. The structure of claim 5, wherein said first barrier metal layer comprises titanium, copper and the combination thereof.

7. The structure of claim 1, wherein said first dielectric layer is a material selected from diluent, filler, photoinitiator, BCB, SINR (Siloxanes polymer), epoxy, polyimides or resin.

8. The structure of claim 2, wherein said second dielectric layer is a material selected from diluent, filler, photoinitiator, BCB, SINR (Siloxanes polymer), epoxy, polyimides or resin.

9. The structure of claim 2, wherein said metal in said solder ball is tin containing material.

10. The structure of claim 1, wherein said multi-metal layer has a portion that extends outside said second opening over said second dielectric layer.

11. A method for creating an under bump metallization for a semiconductor package, comprising the steps of:
providing a substrate with a die having a bonding pad formed thereon;
forming a first dielectric layer over said substrate;
removing a portion of said first dielectric layer to create a first opening to expose said bonding pad;
depositing a first metal layer within said first opening and over said pad, and extending over said first dielectric layer;
forming a redistributed metal layer in said first opening and over said first metal layer; and
forming a multi-metal layer over said redistributed metal layer, wherein said multi-metal layer includes a first barrier metal layer, and a second metal layer formed on said first barrier metal layer; said multi-metal layer having a dimension to support a solder ball, to prevent metal in said solder ball from migrating into said redistributed metal layer.

12. The method of claim 11, wherein said first metal layer comprises titanium, copper and the combination thereof.

13. The method of claim 12, wherein said redistributed metal layer comprises a first metal layer including copper and a second metal layer including gold.

14. The method of claim 13, further comprising a step of forming a second dielectric layer over said first dielectric layer after forming said redistributed metal layer.

15. The method of claim 14, further comprising a step of removing a portion of said second dielectric layer to create a second opening to expose said redistributed metal layer after forming said second dielectric layer.

16. The method of claim 15, further comprising a step of forming a first barrier metal layer within said second opening and over said redistributed metal layer after removing a portion of said second dielectric layer from said second opening.

17. The method of claim 16, wherein said first barrier metal layer comprises titanium, copper and the combination thereof.

18. The method of claim 11, wherein said first dielectric layer is a material selected from diluent, filler, photoinitiator, BCB, SINR (Siloxanes polymer), epoxy, polyimides or resin.

19. The method of claim 14, wherein said second dielectric layer is a material selected from diluent, filler, photoinitiator, BCB, SINR (Siloxanes polymer), epoxy, polyimides or resin.

20. The method of claim 15, wherein said multi-metal layer has a portion that extends outside said second opening over said second dielectric layer.
